(19) United States
(12) Patent Application Publication
(10) Pub. No.: US 2005/0251716 A1
(43) Pub. Date: Nov. 10, 2005

(54) Software to test a storage device connected to a high availability cluster of computers

(75) Inventor: Jean-Luc Degrenand, Mountain View, CA (US)

Correspondence Address: HARRINGTON & SMITH, LLP, 4 RESEARCH DRIVE, SHELTON, CT, 06484-6212, US

(73) Assignee: International Business Machines Corporation

(21) Appl. No.: 10/841,171

(22) Filed: May 7, 2004

(51) Int. Cl. G01R 31/28; G06F 11/00

(52) U.S. Cl. 714/736

(57) ABSTRACT

A computer software program particularly adapted to run on separate nodes of a cluster of computers validates a target storage device, even when one node fails and a clustering software failover mechanism passes the testing function to another node mid-test. The software first tests for a pre-existing index. If present and non-zero, pre-existing blocks of test data on the target device are compared against a known pattern in a shared reference file in a first loop. In a middle loop, additional copies of the blocks of test data are written from the shared file to the target device until full and an index is incremented with each new write. In a final loop, each stored block of test data is compared against the shared file. If no pre-existing non-zero index is found, the node running the software creates an index file and runs the middle and final loops as above, erasing or overwriting all pre-existing data and files.

### TECHNICAL FIELD

The present invention relates to software used to test individual computers and storage devices that may reside within a cluster of redundantly coupled computers.

### BACKGROUND

A multitude of reasons exist for backing-up data. The conversion by most companies from mainframe and mid-range computing systems to applications and file servers initially sacrificed some of the reliability that was built into mainframe systems, reliability that represented decades of engineering. To make their products more amenable for enterprise use, server manufacturers invented sophisticated designs that offer redundant systems and subsystems to recapture the reliability lost in abandoning mainframe systems. Examples include dual power supplies, dual LAN interfaces, multiple processors, and the like. While redundancy generally refers to hardware systems as in the above example, it is increasingly practiced for software systems and individual application programs. Adverse impact due to the failure of an individual component within a particular server is limited by this redundancy. Extending this strategy of redundancy has led to multiple servers running identical applications, termed clustering. Failure of a single server, or of a hardware component or an application of one server, is isolated from impacting system performance by shifting users of the malfunctioning server to one or more other servers.

The software used to re-assign users from a failed network component to an operational one is fairly complex, as it must do so with minimal system disruption and preferably be invisible to the shifted users. Clustering software for high-availability systems, those designed to have very limited downtime, may trigger automatically on the failure of a hardware component, a protocol, or an application. The recovery process from such a failure must preserve network addressing, open applications and files, addressing, current status, and a variety of other data so that the user may continue with minimal and preferably no interruption from network repair activity. Clustering software sometimes includes the ability to balance load among various servers to increase system performance, even where no failure is present.

FIG. 1 is a prior art schematic view of a fully redundant, arbitrated loop, clustered network 20 having nine servers 22A-C, 24A-C, and 26A-C. Two multi-port loop hubs 28A, 28B are configured as primary 34A and backup 34B paths, respectively, between the servers 22A-26C and shared RAIDs (redundant array of independent discs) 30A, 30B. Clustering software must monitor the status (i.e., operational or malfunctioning) of hardware components and of applications on the various servers, and inform other servers in the cluster if a failure or loss of service has occurred on one of them. This status is sometimes termed a heartbeat, and it is typically dispersed through the cluster of servers by a dedicated and sometimes redundant LAN interface separate from the primary and secondary data loops 34A-B. As illustrated in FIG. 1, the heartbeat is propagated through redundant Ethernet links 32A, 32B. Where redundant paths 34A-B to data are desirable, as is usually the case, each server 22A-26C must also monitor the status of each separate connection to the separate storage arrays 30A-B and redirect traffic if a loop or pathway fails. In addition, the storage arrays 30A-B may themselves be made redundant through local or remote RAID mirroring, which continually updates a backup copy of data on the primary RAID in the event it fails.

Since the clustering software determines how a failover mechanism will operate (e.g., which server will recover from a failure of a particular component/application at another server), the clustered servers 22A-26C may be divided into subgroups defined by such recovery policies. In FIG. 1, three subgroups 22A-C, 24A-C, and 26A-C are illustrated. While all servers 22A-26C share a common database application, each subset 22, 24, 26 may be configured for failover of specific applications. For example, failure of a particular application at one server in a subgroup (e.g., server 22A) will be compensating by transferring functions and/or users to identical applications running on the other servers in that same subgroup (e.g., servers 22B and 22C), so that the failure has no impact on servers outside that group (e.g., servers 24A-C and 26A-C).

Because reliability in a clustered system is purposefully enhanced by means of he redundancy described above, a difficulty arises in validating that individual components of the system are operating properly. For more stubborn problems, a fibre channel analyzer can capture and decode frames or packets moving through the system 20 to furnish a level of detail that may be used to properly diagnose a failure on any node. However, these analyzers are generally used as a last resort, as they remain expensive and require a highly trained operator to efficiently determine which packets to capture and to properly interpret the results. Validating and testing the integrity of data storage devices 30A-B, and of the failover mechanism of clustering software, is rendered a bit more complex once the clustered nodes are put into operation. For example, when the failover mechanism of the clustering software triggers (that is, when a component fails) while a block of data is being written to a storage device, that block of data may be lost since the recovering node takes over at a time after that writing that data block was initiated but before it is completely stored, even though the entire block may be in a buffer. When the clustered system 20 is a high availability system, individual components such as servers 22A-26C and storage devices 30A-B cannot be routinely disconnected from the system without undermining the system's high availability rating, unless of course the system designed to meet the target availability rating with missing components.

Some clustering software validates data using a cyclic redundancy check CRC. While effective, this technique adversely impacts performance because it requires additional processor overhead to calculate and compare the CRC values. Systems using CRC are typically adaptable so that data validation occurs only on the nodes bearing the highest value data. Reducing the frequency of CRC checks reduces processor overhead, but increases the volume of data that could be lost when a failure occurs soon after a valid CRC. What is needed in the art is a simple way for a node in a clustered system to validate whether or not a storage device is operational. It would be particularly advantageous to validate a data storage device in a simple manner so that a system may maintain its high availability rating without designing for a storage device to be taken out of the system for testing.

### Summary of the Preferred Embodiments

The foregoing and other problems are overcome, and other advantages are realized, in accordance with the presently preferred embodiments of these teachings. In one embodiment, the present invention is a signal bearing medium (e.g., a computer hard drive, an optical or magnetic storage disk, an MRAM circuit) that tangibly embodies a program of machine-readable instructions executable by a digital processing apparatus to perform operations to test a data storage system, such as a logical unit of computer storage media. The present invention may be embodied as a software program or application on a CD-ROM, a computer hard drive, and the like. The data storage system may be a disk, a volume, or any logical partition of a storage array. The operations include determining whether a data storage system has a first block of test data stored in a first storage region of the data storage system. This is preferably done by searching for an index file having a non-zero index value, and preferably the search is limited to the data storage system being tested. In this preferred aspect, the mere presence of such an index file informs the searching entity that the first block of test data does exist on the data storage system. Such an index file and first block of test data are pre-existing to the operations performing the test. If the determination is positive, the operations further compare the first block of test data to a reference data pattern. If the first block matches the reference data pattern, the operations further copy the reference data pattern to a second storage region of the data storage system. In other words, the first block matches the reference data pattern is not overwritten or erased by new copies of the reference data pattern. The operations then compare the copied block of data in the second storage region, to the reference data pattern, and reports an error if the copied block of data pattern does not match the reference data pattern.

In yet another embodiment, the invention is a system that includes a first computer having at least two input/output data ports for redundantly coupling to each of a second computer and to a data storage array. Preferably, when the first computer is so coupled, it forms a node of a high-availability clustered network. The first computer is operable to search a logical unit of the data storage array for an index file having a non-zero index. If the index file is found in the search, the first computer is operable to compare a first block of test data stored on the logical unit to a block of patterned reference data that is stored apart from the logical unit. If the first block compares favorably to the block of patterned reference data, the first computer is then operable to copy the block of patterned reference data at least one time to the logical unit. Specifically, it is operable to copy the block only to portions of the logical unit that the favorably compared first block is not stored.

However, if the pre-existing index file is not found in the search, the first computer is operable to create a new index file and to copy the block of patterned reference data n times to n different storage regions of the logical unit until the logical unit is substantially filled with n copies of the block of patterned reference data. The index value n in the created index file is incremented each time the block of patterned reference data is copied, and n is a positive integer.

Whether the index file is found in the search or a new index file is created, the first computer is operable to compare each copied block or test data on the logical unit to the block of patterned reference data that is stored apart from the logical unit, and to output an error message if any copied block does not favorably compare. In this embodiment, a favorable comparison is preferably identical data blocks.

Further details of the invention and various aspects of different embodiments are detailed below.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1 is a prior art schematic diagram of a clustered computer system.

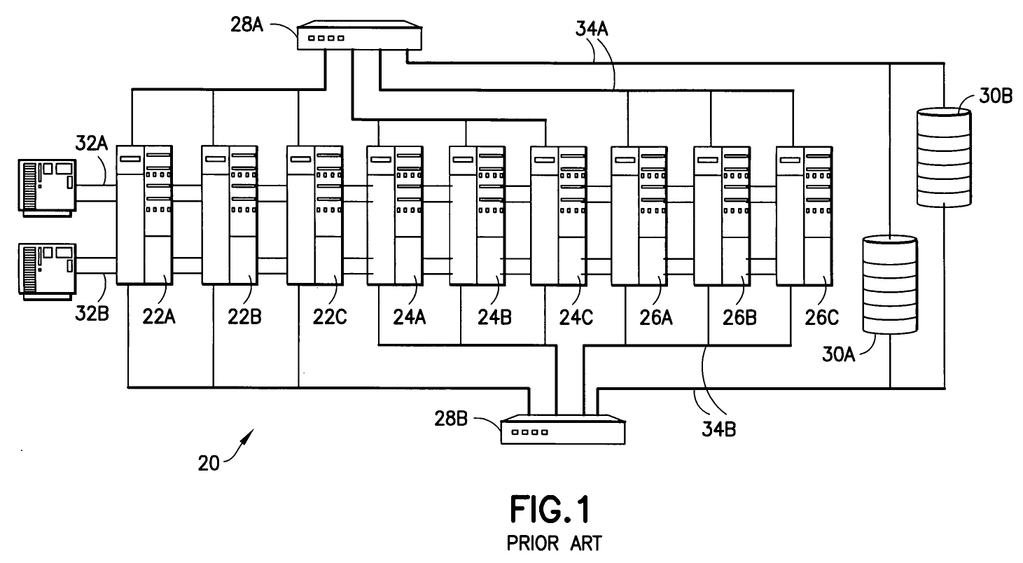

FIG. 2A is a clustered computer system employing the present invention operating in a normal mode.

FIG. 2B is similar to FIG. 2A but after a node has failed and showing operation of the invention as compared to FIG. 2A.

FIG. 3 is a flow diagram describing the logical steps that the inventive computer program according to the preferred embodiment directs a computer to perform.

FIG. 4 is a schematic view of and index and blocks of test data stored in a target storage device, and a shared file used to write those blocks of test data.

### DETAILED DESCRIPTION OF THE PREFERRED EMBODIMENTS:

The following terms are used throughout this description and are defined as follows. An application is a set of processes or computer instructions that can run on a computer or system to provide a service to a user of the computer or system, and does not include the operating system portion of the software. A cluster is two or more computers or nodes in a system used as a single computing entity to provide a service or run an application for the purpose of high availability, scalability, and/or distribution of tasks. Failure is the inability of a system or component thereof to perform a required function within specified limits, and includes invalid data being provided, slow response time, and inability of a service to take a request. A network is a connection of nodes that facilitates communication among them, usually by a well-defined protocol. High availability is the state of a system having a very high ratio of service uptime as compared to service downtime. High availability for a system is typically rated as a number of nines, such as five-nines (99.999% service availability, equivalent to about 5 minutes of total downtime per year) or six-nines (99.9999%, or about thirty seconds of total downtime per year). A node is a single computer unit in a network that runs with one instance of a real or virtual operating system. A user is an external entity that acquires service from a computer system, and it can be a human, an external device, or another computer. A system includes one or more nodes connected via a computer network mechanism. Failover is the ability to switch a service or capability to a redundant node, system, or network upon the failure or abnormal termination of the currently active node, system, or network. A lock service is distributed and suitable for use in a cluster where processes in different nodes might compete with each other for access to shared resources. For example, a lock service may provide exclusive and shared access, synchronous and asynchronous calls, lock timeout, trylock, deadlock detection, orphan locks, and notification of waiters.

In a preferred embodiment, the present invention is a software application that resides on a node of a high availability network. 20, stored on a computer readable medium such as a disk, a MRAM circuit, or the like. This application is for testing purposes only, and does not operate on the substantive data flowing through the network 20. To test and validate a storage device 30A-B, the present software application need reside on only one network node. In order to validate the clustering software failover mechanism, copies of the present software application must reside on at least two nodes of the network that are related by the failover mechanism. Examples of currently available clustering software include MC ServiceGuard (available through Hewlett-Packard of Palo Alto, Calif.), HACMP (available through IBM of Armonk, N.Y.), and SunCluster (available through Sun Microsystems of Santa Clara, Calif,).

The software application writes a block of test data to a storage device 30A-B. In order that the software application is also able to test the failover mechanism, the block of test data should be a shared file accessible by each of the at least two nodes that are related by the clustering failover mechanism. The block of test data is preferably reserved for testing system components, and exhibits a known pattern that is recognizable as test data in order to efficiently distinguish the test data from any other substantive data being propagated through the system 20. While there are an infinite variety of such test data patterns, simple variations include a checkerboard pattern (e.g., “1010101010”), a waltz pattern (e.g., “100100100”), and a sequential counting pattern (e.g., “001010011100101110111”). The block of test data is finite, that is, a single block does not extend a pattern indefinitely but consists of a finite number of data bits.

Physically distinct storage devices 30A-B are typically divided into logical subsets of storage units, sometimes termed a volume. These volumes are typically identified by a logical unit number LUN. A single RAID 30A-B may include thousands of volumes, but the size of a volume is relatively arbitrary; it represents only some logical division of storage capacity and not a universal norm. The software application repeatedly writes the data block to a logical unit of storage to be tested (whether that logical unit is a physically separable disk, a volume, a group of MRAM cells, etc.), and increments a counter each time the write is successful. This continues until the particular data storage volume to be tested is full of only the patterned test data though some storage areas less than the size of the test data block may not have the test data, as there is insufficient storage capacity to copy the entire block of test data again).

An input-output IO generator, as is well known in the art, operates with the inventive software application to direct which data is to be written to which volume. The IO generator generates, for example, an IO flag that designates that the operation to be performed is a read or a write operation, a time when the IO request is generated, the size of the data in this IO request, the LUN for the target volume, and the first LUN block number that this IO will access. These parameters are within the prior art, but in this instance are adapted to the specific writing of the patterned test data to the storage volume to be tested (or to any volume where only the failover mechanism is to be tested).

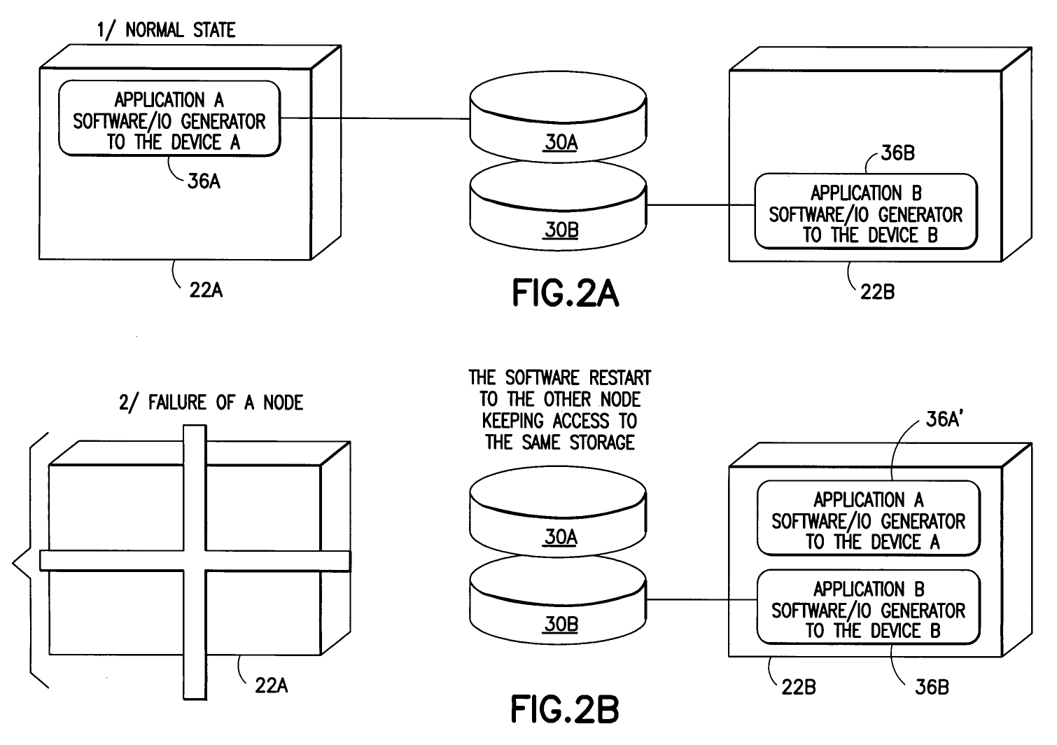

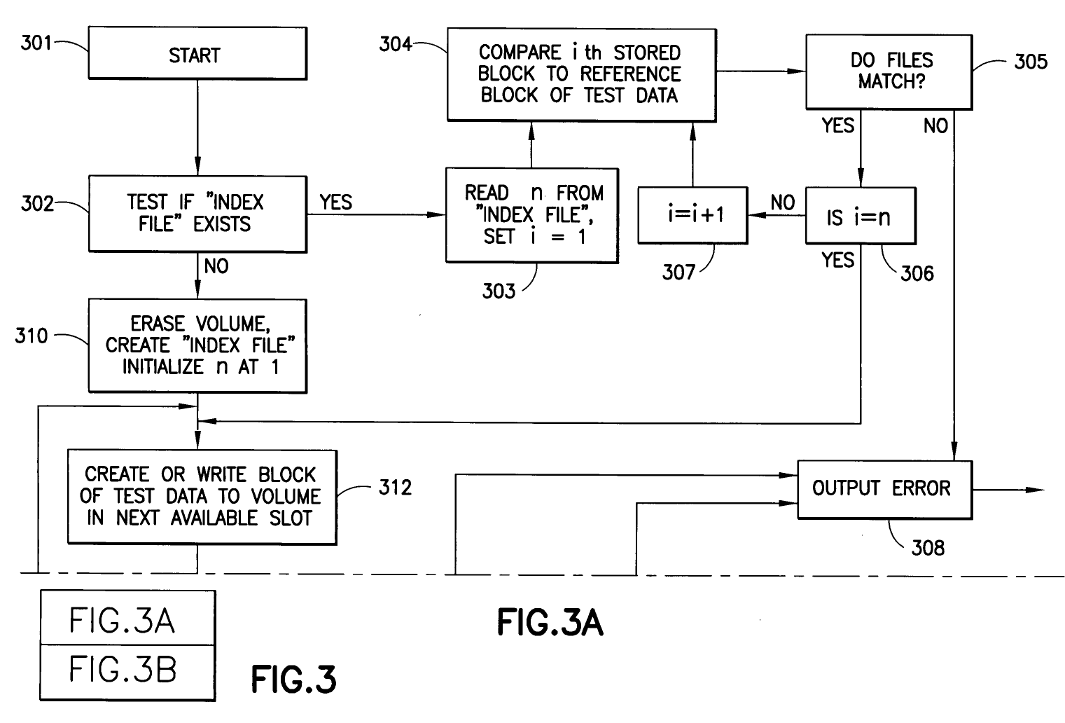

FIG. 2A-2B show conceptually how the present software application validates both a data storage device 30A-B (or volume of it) and a clustering software failover mechanism. In each, the inventive software application and corresponding IO generator is installed on each of a first network node 22A and a second network node 22B. These nodes are computing nodes having a capacity to perform computer processing, as distinct from a storage-only node. A first version 36A of the inventive software application (with IO generator) is installed on the first network node 22A. In normal operation, that first version 36A writes the patterned test data to a first storage device 30A (or a volume or volumes of that device). Similarly, a second version 36B of the inventive software application (with IO generator) is installed on the second network node 22B. In normal operation, that second version 36B writes the patterned test data to a second storage device 30B (or a volume or volumes of that device). The difference between the versions 36A-B need merely be the particular volume or device 30A-B to which they normally write the test data. That difference is preferably reflected in the IO generator.

When one of the computing nodes fails, such as the first node 22A in FIG. 2B, another copy of the application software 36A′ begins to run on the second node 22B. Preferably, this copy 36A′ is identical to the original 36A, though minor disparities may be advantageous to conform to various system anomalies. The second node 22B initiates running of its copy 36A′ of the application in response to signaling by the failover mechanism of the clustering software that the first node 22A has failed. This particular aspect, signaling one node to take over a function from a failed other node, is already embodied generally within commercially available clustering software. The second node 22B then uses its copy of the application 36A′ to write the same patterned test data to the same storage device 30A on which testing was begun but not completed by the first node 22A. Because both nodes 22A, 22B, test a storage device 30A, 30B using the same test data pattern, preferably the application 36A, 36A′, 36B accesses a file that is shared over the network 20 from which to copy and write that patterned test data. Alternatively, the nodes 22A, 22B may access a file that stores an algorithm by which copies of the software application 36A, 36A′ generate identical test data patterns. As will be detailed below, when the first node 22A fails after writing to some but not all of the storage device 30A to be tested, the software application 36A′ that is initiated in response to the clustering software failover mechanism reads the storage volume 30A and writes the patterned test data only to those portions that the patterned test data is not already written. While FIGS. 2A-2B are described with reference to different versions 36A, 36B of the software application for normally writing to different storage devices 30A, 30B, efficiencies may be gained in having only one copy of the application software on each node, with various software decision branches causing the application to different storage devices 30A, 30B. By evaluating whether the second node 26B wrote to the target storage device 30A after purposefully disconnecting the first node 22A (or otherwise interrupting its running of the inventive software application 36A), the failover mechanism of the clustering software may be quickly and efficiently validated.

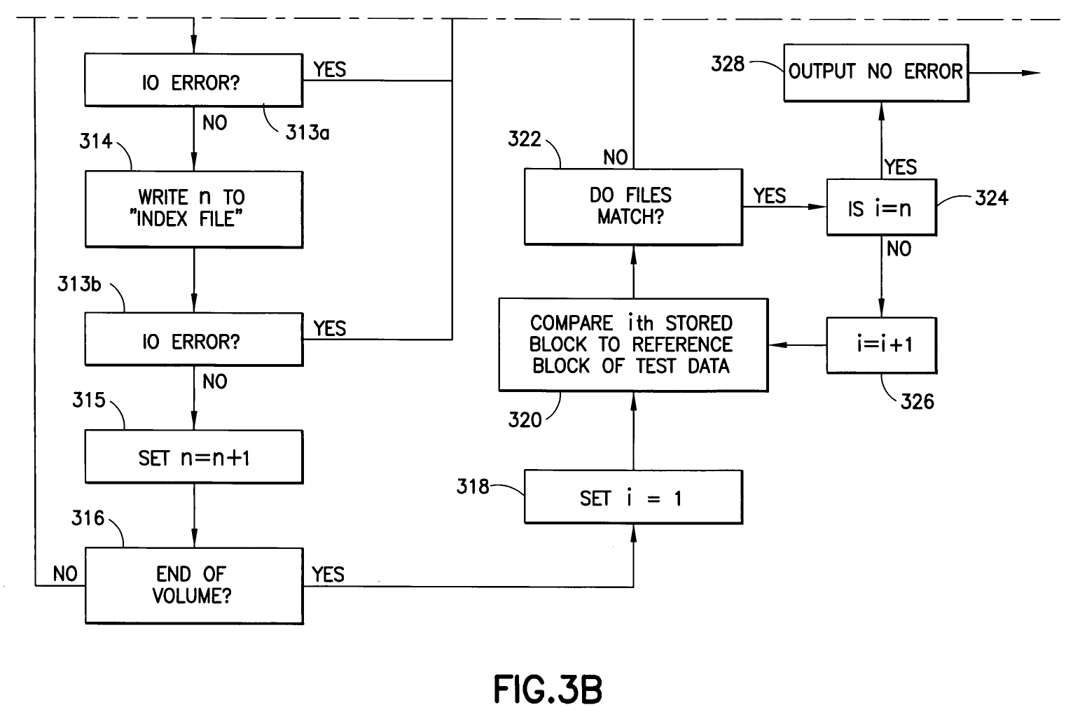

Further specifics as to validating data storage are illustrated in the flow diagram of FIG. 3. Any logical unit of data storage may be evaluated, whether an individual disk, a volume that may occupy only a portion of a disk or be dispersed among several disks, an arrangement of MRAM cells, or any other logical unit of data storage. For brevity, the relevant storage unit will be referred to in this description of FIG. 3 as the target storage device 30A. The inventive software application begins at block 301. Blocks 302-307 relate to testing whether and to what extent another copy of the inventive software application, such as was described above with reference to FIGS. 2A and 2B, previously attempted validating the target storage device 30A. At block 302, the software application tests whether an index file exists, titled in block 302 as “Index File”. Preferably, the “Index File” exists, if at all, on the target storage device 30A, though it may alternatively be stored at another known location and particularly corresponding only to the target storage device 30A.

Presence of an “Index File” is found at block 302 indicates that another node has begun but has not completed writing the patterned test data to the target storage device 30A. The value of the index in the Index File, n, is read at block 303, and the application software initializes the value of an internal index i equal to one. The loop represented by blocks 304-307 compares each block of data that was stored in the target storage device 30A prior to the start block 301 (since this pre-stored data was stored, for example, by the first node 22A of FIG. 2A and interrupted as in FIG. 2B) against the block of test data, which is preferably stored elsewhere apart from the target storage device 30A. The internal index value i tracks which of the blocks of data on the target device 30A is being tested, and the loop 304-307 continues and the internal index i is incremented for only so long as the comparison finds the blocks identical. If a previously stored block of data does not match the original block of patterned test data, an error is output at block 308. A ‘no’ response to block 305 may also or alternatively lead to erasing the entire target storage device 30A at block 310 and continuing the flow diagram from that point. This allows for testing the entire target storage device 30A despite an error that may have resulted from a malfunction in a previous node's write ability, rather than the target's storage ability.

The value n in the Index File that is discovered at block 302 was stored by another node 22A that began testing the target device 30A, and has not changed to this point. It reflects the number of patterned data blocks that the previous node ‘thinks’ it wrote to the target device 30A. Once the value of the internal index i equals the value of the “Index File” index n at block 306, there is no need to read the target storage device 30A further and the flow diagram continues at block 312. However, it is most likely that any error will be reflected in the n^{th} block of test data (the block last stored by the other or first node 22A). This is because the first node 22A may have improperly incremented the index n after writing the block of test data to a buffer. For example, the first node 22A may have been interrupted in its test of the target storage device 30A while the buffer was writing that n^{th} block of test data to the target storage device 30A, but before writing from the buffer was completed. In that instance, the index may reflect a value n but only n−1 blocks will have been properly stored in the target storage device 30A. Therefore, only a little accuracy is lost if the loop 304-307 tests only the n^{th} block of test data rather than each of the n blocks of test data, and the internal index i is unnecessary in this loop 304-307.

In the event the search at block 302 results in no current “Index File”, or if that file is found but the value of n is one (or zero if so initialized), then at block 310, the entire target storage device 30A is erased and an “Index File” is created, with n initialized at one. Any pre-existing data or files previously stored on that device 30A to be tested are deleted at block 310, such as by a re-formatting operation. While the instance of n being found to be zero at block 302 is not depicted in FIG. 3, it would occur when the first node 22A was interrupted after creating the “Index File” but prior to writing the first block of test data to the target storage device 30A. Alternatively, the target storage device 30A need not be erased or (re-)formatted but merely re-indexed so that any pre-existing data is overwritten. Such overwritten pre-existing data excludes any pre-existing stored blocks of test data that pass the comparison of the first loop 303-307. This may be by the specific arrangement of FIG. 3, or by a more particularized re-indexing should the loop of 303-307 not bypass block 310

The next loop 312-316 of FIG. 3 writes the block of test data, preferably from another storage location, to the target storage device 30A until it is substantially full. As above, this generally includes writing the block of test data to a buffer and then to the target storage device 30A. The target storage device 30A is substantially full when it no longer has the capacity to accept another full block of test data without overwriting other data. Preferably, the only other data on that target storage device is the “Index File” that stores the value of the indices n and i, and previously written blocks of patterned test data. Those previously written blocks of test data may have been written by the second node 22B at the loop 312-316, or some of them may have been written by the first node 22A that was evaluated by the second node 22B at the loop 304-307. Each time a block of test data is written at block 312 to the target storage device 30A, the value of the index, n is incremented at block 315 and the remaining capacity of the target storage device 30A is evaluated at block 316. Optionally, an input-output (IO) error is tested at block 313a after writing the test data at block 312, and again at block 313b after writing the index value n to the Index File. IO errors may be output 308 as they are sensed or stored and output en masse following testing of the entire target storage device 30A. Testing of the device 30A may continue upon discovering one error, or may terminate without testing the entire device 30A. When the End of Volume query of block 316 results in a yes, the value of n reflects the maximum number of blocks of test data that the target storage device 30A is capable of storing (save the capacity occupied by the index files).

When the target storage device 30A is substantially full, the ‘yes’ option from block 316 leads to block 318, where another internal index i is initialized to one. Since the inventive software application does not, in the preferred embodiment, run the loops 304-307 and 320-326 simultaneously, there is no need for separate i indices. At the loop 320-326, each block of test data that was written to the target storage device 30A is compared against the original block of test data that was used to write from. That original block of test data is preferably stored in a file that is shared among the network nodes, and should be in a volume separate from the target storage device 30A being tested. Because each and every block of test data stored on the target storage device 30A is evaluated against the original in the loop 320-326, evaluating only the n^{th} block of test data in the loop 304-307 does not undermine the ultimate validity result for the target storage device 30A.

Similar to the loop 304-307, comparison of each block of test data to the original is predicated on the previous block passing the comparison. If a comparison fails at block 322, an error is output at block 308. If all n blocks compare favorably with the original, the final comparison will be characterized by the indices i and n being equal at block 324, and a ‘No Error’ or ‘Valid’ message may be output at block 328. While not depicted, a “No Error” result may be preceded or followed by erasing the target storage device 30A in order that another node testing that same device using the same software application not construe the presence of the “Index File” as an interrupted test by the node that output the “No Error” message. Alternatively, the third loop 320-326 may feed back into block 310 so that the target storage device 30A is continually tested until the software application of the present invention is interrupted to put the target storage device to use.

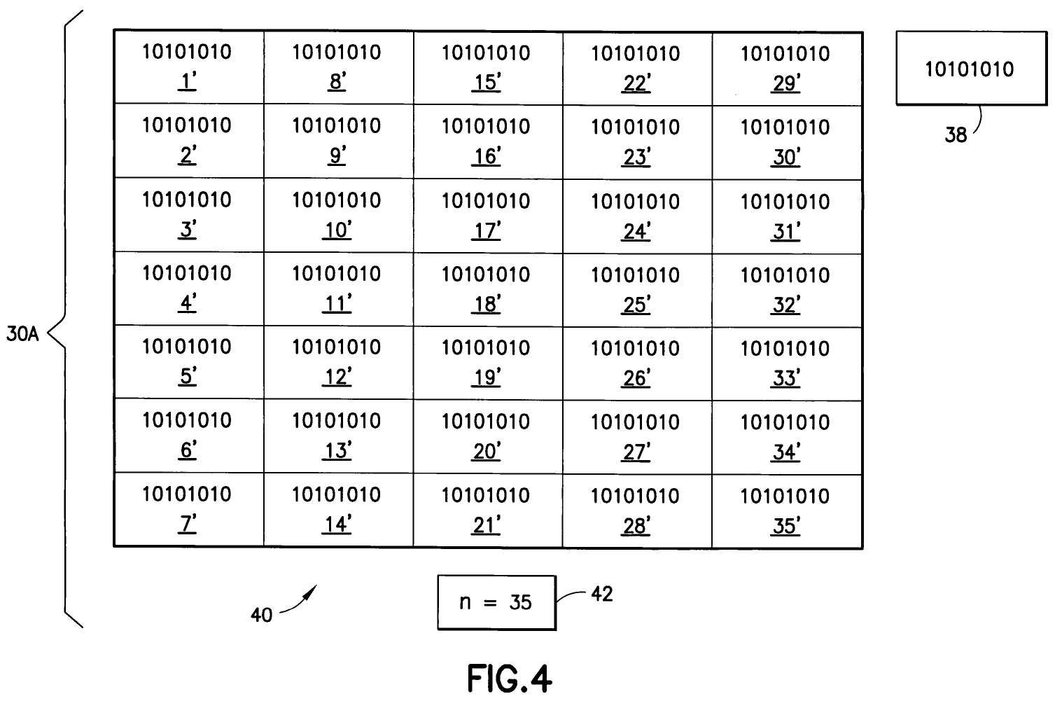

The details of FIG. 3 being explained, the concept of switching between two nodes to test a single target storage device 30A is illustrated schematically at FIG. 4. Assume for FIG. 4 that the block of patterned test data comprises the bits “10101010” and is stored in a shared reference file 38 separate from a target volume to be validated. Assume further that the target storage device 30A has capacity, when fully functional, to store thirty-five copies of the block of test data 40, and a counter 44. Each copy of the block of test data stored on the target storage device 30A is identified by primed numbers 1′-35′. A first node 22A runs the software application according to the flow diagram of FIG. 3, finding no “Index File” at block 302, and creating it at reference number 42 after erasing any residual data that may be on the target storage device 30A, as in block 310 of FIG. 3. Assume that the first node 22A is interrupted after writing, for example, the twelfth block of test data 12′ to the target storage device 30A, but prior to writing the thirteenth 13′. By block 315 of FIG. 3, the final value of n in the “Index File” is twelve when the first node fails.

As above, the normal failover mechanism of the system 20 clustering software assigns the testing of the target storage device 30A to the second node 22B, which then begins running its copy of the software application 36A′ consistent with FIG. 3 at block 301. The second node 22B finds at block 302 of FIG. 3 that the “Index File” does exist, and reads at block 303 of FIG. 3 that the value of n is twelve, as stored by the first node 22A. Throughout the first loop 304-307, the second node validates each of the twelve blocks 1′-12′ of test data previously stored on the target storage device 30A by the first node 22A. Since the first node 22A wrote its twelve copies 1′-12′ from the shared reference file 38, comparison of those twelve copies 1′-12′ to the same shared file 38 by the second node 22B should be favorable so long as the first node 22A wrote correctly and the target storage device 30A stored them correctly. Both the “Index File” and the twelve copies 1′-12′ of the block of data storage are pre-existing to the second node 22B running the inventive software application of this invention, because they were created by the first node 22A. The value of n remains twelve at this juncture. Block 312 of FIG. 3 is entered from block 306, and the remainder of the target storage device 30A is populated to the maximum extent possible with additional copies of the block of test data, written from the shared reference file 38 by the second node 22B. The second node 22B increments the index value n with each successful writing of an entire block of test data to the target storage device 30A. In the loop of FIG. 3 represented by blocks 320-326, each copy 1′-35′ of the block of test data stored on the target storage device 30A is compared against the reference block of patterned test data, the shared reference file 38.

It is apparent that a larger block of test data will result in a lower maximum number for the counter, given the same capacity in a target device 30A. While larger blocks of test data may speed validation of a volume, smaller blocks of test data isolate problem areas more precisely.

Certain variations of the flow diagram of FIG. 3 are evident, and included within the ensuing claims. For example, the loop 304-307 of FIG. 3 may evaluate only the n^{th} copy of the block of test data as detailed above, and the loop 320-326 may compare each of the n blocks. Alternatively, the first loop 304-307 of FIG. 3 may evaluate each of the pre-existing n blocks of test data, and the final loop 320-326 may evaluate only those copies stored according to the middle loop 312-316. In this case, the pre-existing value of n read at block 303 would be stored (apart from the value that is changeable at block 315) and retrieved at block 318 so that the value of index i is initialized at the separately stored pre-existing value of n. As an additional alternative, the entire section of blocks 302-306 of FIG. 3 may be eliminated, and any storing of blocks of test data by another node 22A are merely ignored and erased by the second node 22B. These and other variations to the teaching of this invention are herein reserved to the maximum extent allowable as equivalents to the ensuing claims, and no part of this invention is deemed dedicated to the public. The ensuing claims are to be interpreted to include variations and equivalents to the maximum extent consistent with patent validity.

1. A signal bearing medium tangibly embodying a program of machine-readable instructions executable by a digital processing apparatus to perform operations to test a data storage system, the operations comprising:
determining whether a data storage system has a first block of test data stored in a first storage region;
if the determination is positive, comparing the first block of test data to a reference data pattern;
if the first block matches the reference data pattern, copying the reference data pattern to a second storage region in the data storage system different from the first storage region;
comparing a copied block of data in the second storage region to the reference data pattern; and
reporting an error if the copied block of data does not match the reference data pattern.

2. The signal bearing medium of claim 1 wherein copying the reference data pattern comprises repeatedly copying the reference data pattern to substantially all other storage regions of the data storage system other than the first storage region.

3. The signal bearing medium of claim 2 wherein comparing a copied block of data in the second storage region to the reference data pattern comprises comparing each copied block of data in the substantially all other storage regions to the reference data pattern.

4. The signal bearing medium of claim 3 wherein comparing each copied block of data to the reference data pattern comprises, ion a single iterative loop, comparing each copied block of data to the reference data pattern and comparing the first block of test data to the reference data pattern.

5. The signal bearing medium of claim 1 wherein comparing the first block of test data to a reference data pattern comprises comparing each block of test data to the reference data pattern prior to copying the reference data pattern to a second storage region.

6. The signal bearing medium of claim 1 wherein the operations further comprise:
if at least one of the first block of test data does not match the reference data pattern and the data storage system does not have a first block of test data, copying the reference data pattern n times to the data storage system until said system is substantially filled with copied blocks of data, n being a positive integer;
comparing each copied block to the reference data pattern; and
reporting an error if any of the copied blocks does not match the reference data pattern.

7. The signal bearing medium of claim 6 wherein copying the reference data pattern n times comprises creating an index file for storing the value n and incrementing the value of n each time a copied block of data pattern is written to the data storage system.

8. The signal bearing medium of claim 7 wherein the index file is created in the data storage system, and copying the reference data pattern n times comprises copying the reference data pattern n times to n distinct storage regions of the data storage system, each n^{th} location being other than where the index file is stored.

9. The signal bearing medium of claim 1 wherein determining whether a data storage system has a first block of test data stored thereon comprises searching for an index file having a non-zero index value.

10. The signal bearing medium of claim 1 wherein, if the determination is positive and the first block of test data does not match the reference data pattern, the operations further comprising report an error.

11. The signal bearing medium of claim 1 wherein the reference data pattern is stored in a storage region that is physically separated the data storage system being tested.

12. The signal bearing medium of claim 1 disposed within a computer, said computer disposed as a first computing node within an interconnected network of nodes, said data storage system comprising a separate node of the network of nodes, and wherein the reference data pattern is stored in a file that is shared among at least the first computing node and a second computing node.

13. The signal bearing medium of claim 1 wherein said data storage system comprises at least one data storage volume.

14. A signal bearing medium tangibly embodying a program of machine-readable instructions executable by a digital processing apparatus to perform operations to test a data storage system, the operations comprising:
searching for an index file having a non-zero index value and if present, comparing in a first loop at least a first block of test data stored in the data storage system under test to a reference data pattern that is stored apart from the data storage system under test;
if each of the first blocks of test data that are compared to the reference data pattern compares favorably, copying the reference data pattern to the data storage system under test as many times as necessary to substantially fill all storage regions of the data storage system under test on which the first block and the index file are not stored;
if the index file having a non-zero index value is not present, creating an index file and copying the reference data pattern to the data storage system under test as many times as necessary to substantially fill the data storage system under test; and
after copying the reference data pattern, comparing in a second loop each copied reference data pattern on the data storage system under test to the reference data pattern that is stored apart.

15. A system comprising:
a first computer having dual data input/output ports for redundantly coupling to a second computer and to a data storage array, said first computer operable to:
search a logical unit of the data storage array for an index file having a non-zero index;
if the index file is found,
compare a first block of test data stored at a first storage region of the logical unit to a block of patterned reference data that is stored apart from the logical unit;
if the first block compares favorably to the block of patterned reference data, copy the block of patterned reference data to a second storage region of the logical unit;
if the index file is not found in the search,
create a new index file and copy the block of patterned reference data n times to n different storage regions of the logical unit until the logical unit is substantially filled with n copies of the block of patterned reference data, incrementing an index value n in the new index file each time the block of patterned reference data is copied;
if the index file is found in the search or created as a new index file, compare each copied block on the logical unit to the block of patterned reference data that is stored apart from the logical unit, and output an error message if any copied block does not favorably compare.

16. The system of claim 15 further comprising the second computer that creates the index file found in the search and the first block of test data.

17. The system of claim 15, wherein the first computer is further operable to output an error message if the index file is found in the search and the first block does not compare favorably to the block of patterned reference data.

18. The system of claim 15, wherein if the index file is found in the search and the first block compares favorably to the block of patterned reference data, the computer is further operable to copy the block of patterned reference data as many times as necessary to substantially fill all storage regions of the logical unit without overwriting the first block or any other block that favorably compares to the block of patterned reference data, and without overwriting the index file that is found in the search.

19. The system of claim 15 wherein compare a first block of test data to the block of patterned reference data comprises, in a first iterative loop:
compare an initial block of test data stored on the logical unit to the block of patterned reference data;
sequentially compare every other block of test data that is stored on the logical unit and that was not copied by the first computer to the block of patterned reference data only if an immediately preceding comparison of a block of test data to block of patterned reference data was favorable, until the total number of blocks of test data compared in the first loop to the block of patterned reference data equals the non-zero index of the index file found in the search.

20. The system of claim 15 wherein the first computer is adapted to initialize the search of the logical unit for the index file based on an instruction from a clustering software program that implements a failover mechanism of said clustering software program.
